(19) United States
(12) Patent Application Publication
(10) Pub. No.: US 2026/0107474 A1
(43) Pub. Date: Apr. 16, 2026

(54) MEMORY DEVICE COMPRISING A MEMORY CELL WITH OPTIMIZED ACTIVE SURFACE

(71) Applicant: Commissariat à I'Énergie Atomique et aux Énergies Alternatives, Paris (FR)

(72) Inventors: Julien Borrel, Grenoble (FR); Mathieu Faye, Grenoble (FR); Sébastien Ricavy, Grenoble (FR)

(73) Assignee: Commissariat à I'Énergie Atomique et aux Énergies Alternatives, Paris (FR)

(21) Appl. No.: 19/350,186

(22) Filed: Oct. 6, 2025

(30) Foreign Application Priority Data
Oct. 15, 2024 (FR) FR2411171

(51) Int. Cl. H10B 63/00; G11C 5/06; H10B 61/00; H10N 50/01; H10N 50/10; H10N 70/00

(52) U.S. Cl. CPC H10B 63/30; G11C 5/063; H10B 61/22; H10B 63/84; H10N 50/01; H10N 50/10; H10N 70/011

(57) ABSTRACT

A Memory device including a memory cell including: a first selection transistor including an active area formed in a first semiconductor layer; a plurality of interconnection levels stacked on the first semiconductor layer; a bipolar storage element arranged in one of the interconnection levels; a second selection transistor including an active area formed in a second semiconductor layer arranged in another of the interconnection levels arranged between that including the storage element and the first semiconductor layer; and wherein: drain regions of the first and second transistors are connected to a first electrode of the storage element; source regions of the first and second transistors are respectively connected to first and second distinct and mutually independent connection elements.

### CROSS REFERENCE TO RELATED APPLICATIONS

This application claims priority to French application number FR2411171, filed Oct. 15, 2024. The contents of which is incorporated by reference in its entirety.

### TECHNICAL FIELD

The present disclosure generally concerns the field of electronic devices comprising memory cells, particularly resistive memory cells (called RRAM or ReRAM for “Resistive Random-Access Memory”) based on oxide (OxRAM for “Oxide-based Random-Access Memory”) or on metal electrolyte (CBRAM for “Conductive-Bridging Random-Access Memory”), or with magnetoresistive memory cells (called MRAM for “Magnetoresistive Random-Access Memory”).

### PRIOR ART

The main block of a memory is generally formed of an array of memory cells, or “bit cells”. Each memory cell comprises at least one selection transistor enabling to select and to electrically access the memory cell, and at least one storage element in which the storage of the information for the memory cell is performed. The memory cells are electrically coupled to electrical connection elements formed in stacked interconnection levels of the BEOL (Back End Of Line) portion of the circuit comprising the memory.

In an RRAM-type memory cell, each storage element comprises a portion of metal oxide or electrolyte arranged between two electrodes, generally arranged in the form of a vertical stack. P. Polakowski et al, “Ferroelectric deep trench capacitors based on Al:HfO2 for 3D nonvolatile memory applications”, 2014 IEEE 6th International Memory Workshop (IMW), Taipei, Taiwan, 2014, pp. 1-4, describes such a configuration of an OxRAM-type memory cell.

The programming of a storage element can be achieved by using a single transistor coupled to one of the two electrodes of the storage element. Such a transistor forms in this case a unipolar selector of the storage element and may be of PMOS or NMOS type. Such a 1T1R-type memory cell has the advantage of occupying a small semiconductor surface area (footprint), given that only one transistor is formed in the semiconductor layer for this memory cell. On the other hand, such a unipolar selector cannot perform identically operations of different polarities (write and erase operations, involving current flows in different directions) on the storage element, given the asymmetrical electrical properties of a transistor, which depend on its conductivity type (N or P). The write and erase operations implemented in such a memory cell are in this case strongly unbalanced. For example, the selector may be well adapted to performing the write operation, but be heavily overpowered during the memory cell erase operation.

J.-M. Portal et al, “Design and simulation of a 128 kb embedded nonvolatile memory based on a hybrid RRAM (HfO2)/28 nm FDSOI CMOS technology,” IEEE Trans. Nanotechnol, vol. 16, no. 4, pp. 677-686, July 2017, describes an example of a 2T1R-type memory cell comprising two transistors for programming the storage element, one being of NMOS type and the other of PMOS type. Such a memory cell enables to solve problems of imbalance linked to the polarity of the operations to be carried out in the storage element, given that these are implemented with one or the other of the transistors, depending on the polarity of the operation. On the other hand, such a memory cell occupies a large semiconductor footprint (approximately three times greater that of a 1T1R-type memory cell) due to the two transistors to be formed.

A. Levisse et al, “Resistive Switching Memory Architecture Based on Polarity Controllable Selectors,” IEEE Transactions on Nanotechnology, vol. 18, pp. 183-194, 2019,describes the forming of a 1T1R-type memory cell in which the transistor polarity is controllable according to the operation to be implemented. Such a memory cell enables to solve problem of imbalance linked to the polarity of the operations to be carried out, due to the possible programming of the polarity of the transistor. On the other hand, such a memory cell requires a large semiconductor footprint (approximately twice as large as that required for a 1T1R-type memory cell comprising a transistor having a non-controllable polarity) due to the surface area occupied by the transistor of controllable polarity.

### SUMMARY OF THE INVENTION

There thus exists a need to provide a memory device comprising at least one memory cell which does not have the asymmetry or imbalance problems of a unipolar selector memory cell and requiring a smaller semiconductor footprint than known 2T1R or 1T1R type memory cells with a transistor of controllable polarity.

An embodiment provides a solution to all or part of the disadvantages of known solutions and provides a memory device comprising at least one memory cell comprising:
a first selection transistor comprising an active area formed in a first semiconductor layer;
a plurality of interconnection levels stacked on the first semiconductor layer;
a bipolar storage element arranged in one of the interconnection levels;
a second selection transistor comprising an active area formed in a second semiconductor layer arranged in another of the interconnection levels arranged between that including the storage element and the first semiconductor layer;

and wherein:
drain regions of the first and second selection transistors are connected to a first electrode of the storage element;
source regions of the first and second selection transistors are respectively connected to first and second distinct and mutually independent connection elements.

According to a specific embodiment, the storage element comprises a resistive portion and the memory cell is of OxRAM type, or the storage element comprises a solid electrolyte and the memory cell is of CBRAM type, or the storage element comprises a magnetoresistive stack and the memory cell is of MRAM type.

According to a specific embodiment, the active area of the second selection transistor is at least partly arranged vertically in line with the active area of the first selection transistor.

According to a specific embodiment, one of the first and second selection transistors is of type P and the other of the first and second selection transistors is of type N.

According to a specific embodiment, the memory device comprises a plurality of memory cells arranged in an array and addressed in word lines, bit lines, and source lines, and, in each memory cell:
separate word lines are coupled to the gates of the first and second transistors for selecting the memory cell;
one of the bit lines is coupled to a second electrode of the storage element of the memory cell;
separate source lines are coupled to the source regions of the first and second transistors for selecting the memory cell via the first and second connection elements.

According to a specific embodiment:
when the second selection transistor is of type N, the second semiconductor layer comprises semiconductor oxide, or
when the second selection transistor is of type P, the second semiconductor layer comprises carbon nanotubes.

According to a specific embodiment, the second semiconductor layer comprises a crystalline semiconductor material.

According to a specific embodiment, the memory device is made in the form of an integrated circuit in which the first semiconductor layer is included in the FEOL portion of the integrated circuit, and the interconnection levels are included in the BEOL portion of the integrated circuit.

According to a specific embodiment, the first connection element extends through at least a first dielectric layer covering the first selection transistor and the interconnection levels including the storage element and the second selection transistor, and the second connection element extends through at least the interconnection levels including the storage element and the second selection transistor.

According to a specific embodiment, the drain region of the second selection transistor is connected to the first electrode of the storage element by at least a third connection element extending through at least the interconnection level including the second selection transistor, and the drain region of the first selection transistor is connected to the first electrode of the storage element by at least a fourth connection element extending through at least the first dielectric layer and by the third connection element.

There is also provided a method of forming a memory device comprising at least one memory cell, comprising at least:
the forming of a first selection transistor comprising an active area formed in a first semiconductor layer;
the forming of a plurality of interconnection levels stacked on the first semiconductor layer, including at least:
   the forming of a bipolar storage element in one of the interconnection levels;
   the forming of a second selection transistor comprising an active area formed in a second semiconductor layer arranged in another of the interconnection levels arranged between that including the storage element and the first semiconductor layer;
wherein drain regions of the first and second selection transistors are connected to a first electrode of the storage element;
and further comprising a forming of first and second distinct and mutually independent connection elements, and connected to source regions of the first and second selection transistors, respectively.

According to a specific embodiment, the method further comprises, between the forming of the first selection transistor and the forming of the interconnection levels, a forming of a first dielectric layer covering at least the first selection transistor, and the first connection element is formed through at least the first dielectric layer and the interconnection levels including the storage element and the second selection transistor, and the second connection element is formed through at least the interconnection levels including the storage element and the second selection transistor.

According to a specific embodiment, the method further comprises a forming of at least a third connection element through the interconnection level including the second selection transistor and connecting the drain region of the second selection transistor to the first electrode of the storage element, and a forming of at least a fourth connection element through the first dielectric layer and connecting, with the third connection element, the drain region of the first selection transistor to the first electrode of the storage element.

According to a specific embodiment, the memory device is made in the form of an integrated circuit in which the first semiconductor layer is included in the FEOL portion of the integrated circuit and the first selection transistor is formed during the forming of the FEOL portion of the integrated circuit, and the interconnection levels are included in the BEOL portion of the integrated circuit and the storage element and the second selection transistor are formed during the forming of the BEOL portion of the integrated circuit.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a circuit diagram of an example of a memory device according to a specific embodiment;

FIG. 2 shows a cross-section view of an example of a memory device according to a specific embodiment;

FIG. 3 and FIG. 4 show steps of an example of a memory device manufacturing method.

### DESCRIPTION OF EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, various elements (readout circuit, row decoder, column decoder, etc.) of the memory device are not detailed. A detailed implementation of these elements is within the ability of those skilled in the art by using the functional description given below.

In the various drawings, the visible elements are not shown to the same scale as one another to facilitate the understanding of these drawings.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, the term “coupled” is used to designate an electrical coupling between elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings. However, these terms do not presume the actual position and orientation of the device during its use.

Unless specified otherwise, the expressions “about”, “approximately”, “substantially”, and “in the order of” signify plus or minus 10%, preferably of plus or minus 5%.

The following description of oxide-based resistive bipolar memory cells (OxRAM) can be applied in the same way to other types of resistive bipolar memory cells (RRAM), in particular of CBRAM type, by replacing the elements forming these OxRAM memory cells by their CBRAM memory cell equivalents, that is, in particular the lower and upper electrodes by, respectively, a chemically inert electrode and a chemically active electrode, and the resistive layer by a solid electrolyte. It can also be applied to other types of bipolar memory cells, in particular of MRAM type, by replacing the resistive layer with a magnetoresistive stack comprising a tunnel oxide layer, for example based on MgO, arranged between two magnetic layers, for example based on cobalt.

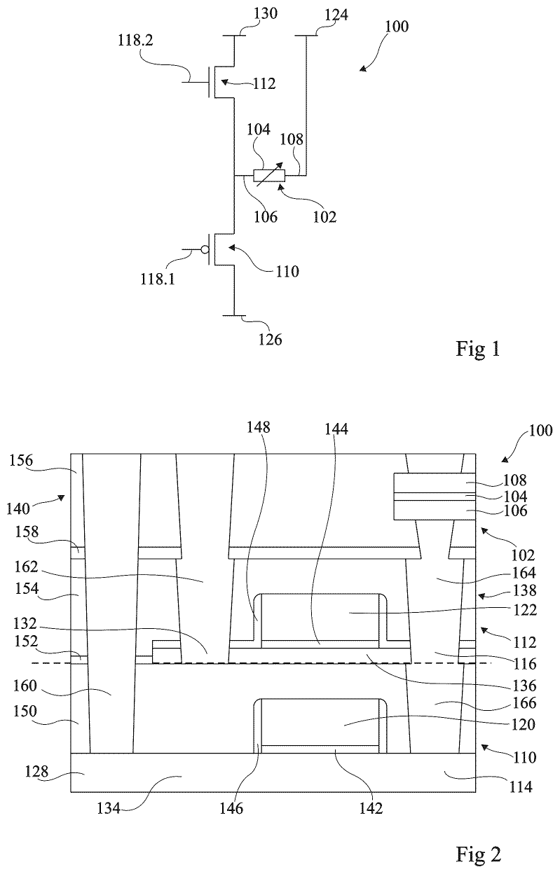

An example of a memory device 100 according to a specific embodiment is described hereafter in relation with FIGS. 1 and 2. In these drawings, a circuit diagram (FIG. 1) and a cross-section view (FIG. 2) of a memory cell of memory device 100 are shown.

In the described example, memory device 100 comprises a plurality of memory cells arranged side by side in the form of an array. In FIGS. 1 and 2, a single memory cell is shown.

Each memory cell of device 100 comprises a bipolar storage element 102 in which information is intended to be stored. In the described example, storage element 102 is of OxRAM type and comprises a resistive portion 104 comprising an oxide having its resistance varying according to the information stored in the memory cell. For example, resistive portion 104 may comprise HfO₂ or any other oxide adapted to storing information by the forming of conductive filaments therewithin.

Resistive portion 104 is arranged between a first electrode 106 and a second electrode 108 of storage element 102. According to an embodiment, each of the first and second electrodes 106, 108 of storage element 102 may comprise a first portion comprising, for example, Ti, TiN or TaN and arranged against resistive portion 104, and at least a second portion comprising, for example, tungsten, TiN, copper, or cobalt and used for the electrical interconnection of storage element 102. In this example, each of the first and second electrodes 106, 108 has its first portion arranged between resistive portion 104 and its second portion. The examples of materials mentioned hereabove for the forming of the first portion of the electrodes 106, 108 of storage element 102 have the advantage of being chemically stable, thus providing electro-chemical neutrality to electrodes 106, 108.

According to an example of embodiment, storage element 102 may optionally comprise a portion of getter material based on titanium, tantalum, hafnium, or any other material having an electro-chemical affinity for oxygen when storage element 102 is of OxRAM type. Such a portion of getter material may contribute to the creation of one or more electrically-conductive filaments in the resistive portion 104.

As a variant, storage element 102 may be of another type, for example, CBRAM or MRAM. In this case, resistive portion 104 can be replaced by another type of portion of material(s) in which information storage is intended to take place.

The memory cell also comprises a first selection transistor 110 and a second selection transistor 112 intended to control storage element 102 during write, erase, and read operations in storage element 102. In the described example, transistors 110, 112 are of MOS type, but other types of transistors can be envisaged. Further, in the described example, the first transistor 110 is of type P and the second transistor 112 is of type N. As a variant, it is possible for the first transistor 110 to be of type N and for the second transistor 112 to be of type P.

A drain region 114, 116 of each of the first and second transistors 110, 112 is connected to the first electrode 106 of storage element 102.

The memory cells of device 100 are addressed in word lines, bit lines, and source lines. Each of the word lines and source lines is, for example, coupled to the memory cells arranged on a same row of the array of memory cells of device 100, and each of the bit lines is, for example, coupled to the memory cells arranged on a same column of the array of memory cells of device 100. Other configurations are however possible, such as for example having the source lines coupled to the memory cells perpendicularly or parallel to the bit lines, having the source and bit lines coupled to the memory cells both perpendicularly to the word lines, etc.

In the described example, the word lines are coupled to the gates of the memory cell selection transistors. In the example of FIG. 1, a first word line 118.1 is coupled to the gate 120 of the first transistor 110, and a second word line 118.2 intended for the transmission of a signal complementary to that transmitted by the first word line 118.1 (since the first and second transistors 110, 112 are of opposite types in this example) is coupled to the gate 122 of the second transistor 112.

In the specific embodiment described herein, the bit lines and the source lines are coupled to source regions of the first and second transistors 110, 112 and to electrodes of the storage elements 102 of the memory cells. In the specific embodiment described in relation with FIGS. 1 and 2, one of the bit lines 124 is coupled to the second electrode 108 of storage element 102, a first source line 126 is coupled to a source region 128 of the first transistor 110, and a second source line 130, distinct from the first source line 128, is coupled to a source region 132 of the second transistor 112.

The first transistor 110 comprises an active area (area including the channel, source, and drain regions of the transistor) formed in a first semiconductor layer 134. In the example of embodiment shown in FIGS. 1 and 2, the first semiconductor layer 134 forms part of a substrate from which device 100 is formed. This substrate may correspond, for example, to a solid substrate, or bulk, or to an SOI substrate (with, in this case, the first semiconductor layer 134 corresponding to the semiconductor surface layer of the SOI substrate). The first transistor 110 may for example be of bulk, FDSOI (Fully-Depleted Silicon On Insulator), or FinFET (Fin Field-Effect Transistor) type.

In the described example, device 100 is made in the form of an integrated circuit which may comprise other electronic circuits. The first semiconductor layer 134 is included in the FEOL (Front End-Of-Line) portion of the integrated circuit. Different interconnection levels are formed above the first semiconductor layer 134, and more precisely above the gates and contacts formed on the first semiconductor layer 134, and form part of the BEOL (“Back End-Of-Line”) portion of the integrated circuit. In FIG. 1, the boundary between the FEOL and BEOL portions of the integrated circuit is symbolized by a dotted line.

The second transistor 112 comprises an active area formed in a second semiconductor layer 136, which is arranged in one of the interconnection levels stacked on the first semiconductor layer 134, and thus in the BEOL portion of the integrated circuit. Similarly, storage element 102 is formed in another of these interconnection levels, and thus also in the BEOL portion of the integrated circuit.

The second transistor 112 and the second semiconductor layer 136 are located in an interconnection level arranged between the first semiconductor layer 134 and the interconnection level in which storage element 102 is formed. For example, the second transistor 112 is located in the M1 or Metal 1 interconnection level, designated by reference 138, located immediately above the BEOL portion of the circuit, and storage element 102 is arranged in the M2 or Metal 2 interconnection level, designated by reference 140, of the integrated circuit.

According to an example of embodiment, storage element 102 may be made in the form of a stack of planar layers or in the form of a 3D structure.

The active area of the second transistor 112 may be at least partly located vertically in line with the active area of the first transistor 110. In the example shown in FIG. 2, the active areas of the first and second transistors 110, 112 are aligned one above the other.

In FIG. 2, the gate dielectrics of the first and second transistors 110, 112, comprising for example an oxide, are respectively designated with references 142, 144, and the gate spacers, comprising for example a nitride, are respectively designated with references 146 and 148 for the first and second transistors 110, 112.

In the described embodiment, the first semiconductor layer 132 comprises, for example, silicon. A first dielectric layer 150, of PMD (Pre-Metal Dielectric) type and comprising, for example, a semiconductor oxide such as SiO₂, is arranged on the first semiconductor layer 134 and covers, in particular, the gate 120 of the first transistor 110 as well as spacers 146.

The second semiconductor layer 136 is arranged on the first dielectric layer 150. A nitride layer 152, for example comprising silicon nitride, covers parts of the second semiconductor layer 136 not covered by gate 122 and spacers 148. Nitride layer 152 also covers parts of the first dielectric layer 150 not covered by the second semiconductor layer 136. The interface between the second semiconductor layer 136 and the first dielectric layer 150, and between nitride layer 152 and the first dielectric layer 150 for the parts of the first dielectric layer 150 not covered by the second semiconductor layer 136, can be seen as forming the separation between the FEOL and BEOL portions of the integrated circuit.

The interconnection level 138 including the second transistor 112 also comprises a second dielectric layer 154, of IMD type (“Inter-Metal Dielectric”, and more precisely IMD1 when interconnection level M1 is concerned), and comprising for example a semiconductor oxide such as SiO₂. The second dielectric layer 154 is arranged on nitride layer 152 and on the second transistor 112, covering it.

The interconnection level 140 comprising storage element 102 also comprises a third dielectric layer 156, of IMD type (“Inter-Metal Dielectric”, and more precisely IMD2 when interconnection level M2 is concerned), and comprising, for example, a semiconductor oxide such as SiO₂. The elements of storage element 102 (resistive portion 104, electrodes 106, 108) are arranged within this third dielectric layer 156.

Another dielectric layer 158, comprising for example semiconductor nitride such as silicon nitride, is arranged between the second and third dielectric layers 154, 156. The interface between the second dielectric layer 154 and this layer 158 can be seen as forming the separation between the interconnection levels 138, 140 of the integrated circuit.

When the second transistor 112 is of type N, the second semiconductor layer 136 comprises, for example, an oxide semiconductor such as indium tin oxide (ITO), indium(III) oxide (In₂O₃), IGZO, indium tungsten oxide (IWO), or polysilicon. When the second transistor 112 is of type P, the second semiconductor layer 136 comprises, for example, carbon nanotubes (CNT). Its thickness is, for example, in the range from 1 monolayer to a few nanometers.

As a variant, the second semiconductor layer 136 may be a layer of crystalline semiconductor material, for example of crystalline silicon.

In each memory cell of device 100, connection elements are present and form the connections between storage element 102, selection transistors 110, 112, and the word, bit and source lines.

In the example of embodiment described in relation with FIGS. 1 and 2, a first connection element 160 couples the source region 128 of the first transistor 110 to source line 126. This first connection element 160 extends through the first dielectric layer 150 as well as the various layers of the interconnection levels 138, 140 (without, however, extending through the second semiconductor layer 136).

In the example of embodiment described in relation with FIGS. 1 and 2, a second connection element 162 couples the source region 132 of the second transistor 112 to source line 130. This second connection element 162 extends through the various dielectric layers of interconnection levels 138, 140.

The first and second connection elements 160, 162 are separate and independent of each other so that, in the specific embodiment described herein, the source regions 128, 132 of the first and second transistors 110, 112 are coupled to different source lines 126, 130.

In the embodiment described in relation with FIGS. 1 and 2, a third connection element 164 connects the drain region 116 of the second selection transistor 112 to the first electrode 106 of storage element 102. This third connection element 164 extends through the various layers of interconnection levels 138, 140 until it reaches the first electrode 106 of storage element 102.

Further, a fourth connection element 166 extends through the first dielectric layer 150 and enables to connect, also due to the third connection element 164, the drain region 114 of the first selection transistor 110 to the first electrode 106 of storage element 102.

For example, the various connection elements present in the memory cell and forming the connections between storage element 102, selection transistors 110, 112, and the word, bit, and source lines, may comprise tungsten, cobalt, or a Ti/TiN stack.

Interconnection levels 138, 140 may comprise other metal interconnection portions, not shown in FIG. 1.

In the example of embodiment described hereabove, the first and second transistors 110, 112 correspond to single-gate transistors. As a variant, it is possible for the gate 122 of the second transistor 112 to be arranged on the side of the other surface of the second semiconductor layer 134, that is, the surface of the second semiconductor layer 134 located on the side of the first selection transistor 110. According to another variant, the first transistor 110 and/or the second transistor 112 may correspond to dual-gate transistors.

An advantageous configuration of device 100 corresponds to that in which the first transistor 110 is of type P and comprises an active region comprising silicon, and in which the second transistor 112 is of type N and comprises an active area comprising indium oxide.

In device 100, the memory cell or each of the memory cells formed as described hereabove has no polarity asymmetry problem, since the storage element 102 of the cell is accessible, from its first electrode 106, via two separate transistors coupled to different source lines 126, 130, having a polarity that can be adapted to the flow direction of current through storage element 102. For example, one of the two transistors 110, 112 has a polarity well suited to the implementation of a write operation into storage element 102, and the other of the two transistors 110, 112 has a polarity well suited to the implementation of an erase operation in the storage element.

Further, the bulk, and more precisely the semiconductor footprint of the memory cell or of each of the memory cells of device 100, is limited by the fact that only the first transistor 110 is formed in the first semiconductor layer 134 of the substrate, and that storage element 102 and the second transistor 112 are formed in interconnection levels 138, 140 stacked on the first semiconductor layer. This bulk is advantageously optimized when the active areas of the first and second transistors 110, 112 are aligned and arranged vertically in line with each other.

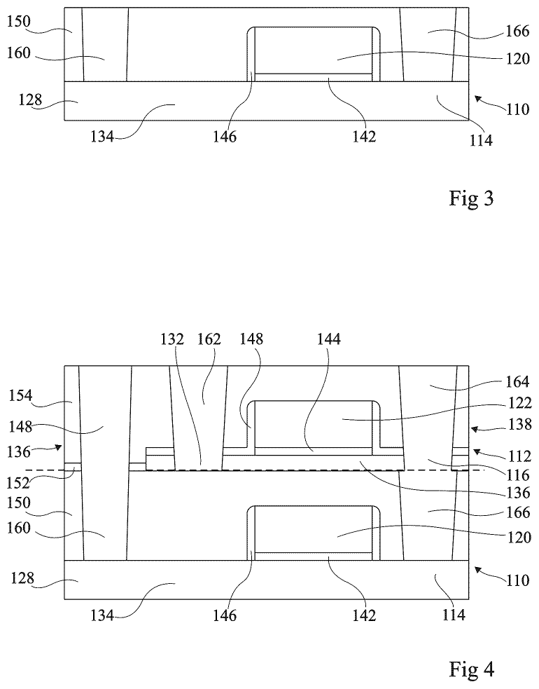

A method of forming device 100 according to a specific embodiment is described hereafter in relation with FIGS. 3 and 4.

As shown in FIG. 3, the first transistor 110 is first formed from the first semiconductor layer 134. The steps involved to form this first transistor 110 are not detailed herein and correspond to conventional steps in the field of integrated circuit manufacturing.

The first dielectric layer 150 is then formed on the first transistor 110 and the first semiconductor layer 134, after which the fourth connection element 166 and the portion of the first connection element 160 located in the first dielectric layer 150 are then formed. For example, the first dielectric layer 150 may first be deposited to the desired thickness. The connection elements may then be formed by etching holes through the first dielectric layer 150, thus forming accesses to the desired parts. One or more metals may then be deposited in these holes, and the metal portions deposited on the first dielectric layer 150 may then be removed, for example by the implementation of a CMP (“Chemical-Mechanical Polishing”). These steps may also form the first word line 118.1. The structure obtained at this stage of the method is shown in FIG. 3.

The first interconnection level 138 is then formed on the resulting structure. For this purpose, the second semiconductor layer 136 is first formed on the previously-formed structure, and thus on the first dielectric layer 150 and the fourth connection element 166. The technique(s) implemented for the forming of the second semiconductor layer 136 depend on the nature of the material(s) of this layer. When the second semiconductor layer 136 comprises semiconductor oxide, the steps enabling its production can be carried out at temperatures below around 400° C. When the second semiconductor layer 136 comprises a crystalline semiconductor material, this layer can be transferred by implementing a low-temperature transfer step, such as described for example in M. Vinet et al, “3D monolithic integration: Technological challenges and electrical results”, Microelectronic Engineering, Volume 88, Issue 4, 2011, pages 331-335.

The second transistor 112 is then formed from the second semiconductor layer 136, after which nitride layer 152 and the second dielectric layer 154 are formed. The connection elements (the third connection element 164) as well as the portions of the connection elements located in the second interconnection level 138 (portions of the first and second connection elements 160, 162) are then formed in the second interconnection level 138. The structure obtained at this stage of the method is shown in FIG. 4.

Nitride layer 158 is then formed on the previously-formed structure, and thus on the second dielectric layer 154 and the various portions and connection elements previously formed in the second dielectric layer 154.

Storage element 102 and the second interconnection level 140 are then formed on nitride layer 158. The third dielectric layer 156 may in particular be formed by implementing a plurality of steps of deposition of the dielectric material desired for this layer, with in particular, between these deposition steps, the implementation of steps forming the various elements of storage element 102. The memory cell obtained by this method corresponds to that shown in FIG. 2.

In the above-described method, only the forming of the elements of a single memory cell of device 100 is described. These steps are however generally implemented for the simultaneous forming of a plurality of memory cells. Further, when device 100 is made in the form of an integrated circuit, other components and elements are formed during the forming of the FEOL and BEOL portions of the integrated circuit.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. For example, the precise nature of the deposition and etching steps implemented can be selected in particular as a function of the material(s) to be deposited or etched, as well as of the thicknesses of material to be deposited or etched.

1. Memory device comprising at least one memory cell comprising:
a first selection transistor comprising an active region formed in a first semiconductor layer;
a plurality of interconnection levels stacked on the first semiconductor layer;
a bipolar storage element arranged in one of the interconnection levels;
a second selection transistor comprising an active area formed in a second semiconductor layer arranged in another of the interconnection levels arranged between that including the storage element and the first semiconductor layer;
and wherein:
drain regions of the first and second selection transistors are connected to a first electrode of the storage element;
source regions of the first and second selection transistors are respectively connected to first and second distinct and mutually independent connection elements.

2. Memory device according to claim 1, wherein the storage element comprises a resistive portion and the memory cell is of OxRAM type, or wherein the storage element comprises a solid electrolyte and the memory cell is of CBRAM type, or wherein the storage element comprises a magnetoresistive stack and the memory cell is of MRAM type.

3. Memory device according to claim 1, wherein the active area of the second selection transistor is at least partly arranged vertically in line with the active area of the first selection transistor.

4. Memory device according to claim 1, wherein one of the first and second selection transistors is of type P and the other of the first and second selection transistors is of type N.

5. Memory device according to claim 1, comprising a plurality of memory cells arranged in an array and addressed in word lines, bit lines, and source lines, and wherein, in each memory cell:
distinct word lines are coupled to the gates of the first and second selection transistors of the memory cell;
one of the bit lines is coupled to a second electrode of the storage element of the memory cell;
distinct source lines are coupled to the source regions of the first and second selection transistors of the memory cell via the first and second connection elements.

6. Memory device according to claim 1, wherein:
when the second selection transistor is of type N, the second semiconductor layer comprises semiconductor oxide, or
when the second selection transistor is of type P, the second semiconductor layer comprises carbon nanotubes.

7. Memory device according to claim 1, wherein the second semiconductor layer comprises a crystalline semiconductor material.

8. Memory device according to claim 1, implemented in the form of an integrated circuit in which the first semiconductor layer is included in the FEOL portion of the integrated circuit, and in which the interconnection levels are included in the BEOL portion of the integrated circuit.

9. Memory device according to claim 1, wherein the first connection element extends through at least a first dielectric layer covering the first selection transistor and the interconnection levels including the storage element and the second selection transistor, and wherein the second connection element extends through at least the interconnection levels including the storage element and the second selection transistor.

10. Memory device according to claim 9, wherein the drain region of the second selection transistor is connected to the first electrode of the storage element by at least a third connection element extending through at least the interconnection level including the second selection transistor, and wherein the drain region of the first selection transistor is connected to the first electrode of the storage element by at least a fourth connection element extending through at least the first dielectric layer and by the third connection element.

11. Method of forming a memory device comprising at least one memory cell, comprising at least:
the forming of a first selection transistor comprising an active area formed in a first semiconductor layer;
the forming of a plurality of interconnection levels stacked on the first semiconductor layer, including at least:
the forming of a bipolar storage element in one of the interconnection levels;
the forming of a second selection transistor comprising an active area formed in a second semiconductor layer arranged in another of the interconnection levels arranged between that including the storage element and the first semiconductor layer;
wherein drain regions of the first and second selection transistors are connected to a first electrode of the storage element;
and further comprising a forming of first and second distinct and mutually independent connection elements, and connected to source regions of the first and second selection transistors respectively.

12. Method of forming a memory device according to claim 11, further comprising, between the forming of the first selection transistor and the forming of the interconnection levels, a forming of a first dielectric layer covering at least the first selection transistor, and wherein the first connection element is formed through at least the first dielectric layer and the interconnection levels including the storage element and the second selection transistor, and the second connection element is formed through at least the interconnection levels including the storage element and the second selection transistor.

13. Method of forming a memory device according to claim 12, further comprising a forming of at least a third connection element through the interconnection level including the second selection transistor and connecting the drain region of the second selection transistor to the first electrode of the storage element, and a forming of at least a fourth connection element through the first dielectric layer and connecting, with the third connection element, the drain region of the first selection transistor to the first electrode of the storage element.

14. Method of forming a memory device according to claim 11, wherein the memory device is made in the form of an integrated circuit in which the first semiconductor layer is included in the FEOL portion of the integrated circuit and the first selection transistor is made during the forming of the FEOL portion of the integrated circuit, and wherein the interconnection levels are included in the BEOL portion of the integrated circuit and the storage element and the second selection transistor are formed during the forming of the BEOL portion of the integrated circuit.
